(19) United States
(12) Patent Application Publication
(10) Pub. No.: US 2009/0146722 A1
(43) Pub. Date: Jun. 11, 2009

(54) Systems and Arrangements to Provide Input Offset Voltage Compensation

(75) Inventors: Minhan Chen, Cary, NC (US); Hayden C. Cranford, Jr., Cary, NC (US); Bobak Modaress-Razavi, Morrisville, NC (US)

Correspondence Address: IBM COPORATION (RTP);C/O SCHUBERT OSTERRIEDER & NICKELSON PLLC, 6013 CANNON MOUNTAIN DRIVE, S14, AUSTIN, TX, 78749, US

(73) Assignee: INTERNATIONAL BUSINESS MACHINES CORPORATION, Armonk, NY (US)

(21) Appl. No.: 11/953,346

(22) Filed: Dec. 10, 2007

(51) Int. Cl. H03L 5/00; H04L 7/00

(52) U.S. Cl. 327/307; 375/354

(57) ABSTRACT

In one embodiment a method is disclosed that includes applying a series of voltages to an input of an offset evaluation latch, detecting an offset voltage from the offset evaluation latch in response to the application of the series of voltages, and applying an offset compensation voltage to the input of a plurality of sampling latch in response to the detected offset voltage. In some embodiments a digital value can be assigned to the applied offset voltage. When the offset voltage is determined, it can be applied to a plurality sampling latches and a data stream can be received and clock and data recovery can be performed.

### FIELD

The present disclosure is related to electrical circuits and more specifically to arrangements for input offset voltage compensation.

### BACKGROUND

Clock signals are utilized in communication systems to synchronize communications such that a receiver can read the data waveform when the amplitude of the data waveform achieves the appropriate value. Such a process is commonly referred to as clock and data recovery (CDR). When the timing of the receiver is synchronized with the data waveform, the waveform on the transmission line will reach a sufficient voltage and the sampling clock of the receiver will trigger acquisition of the data in the waveform. Traditional CDR systems utilize two system clocks or two sampling clock signals to determine an optimum time to read or acquired data from the data waveform on the transmission line.

Ideally, clock and data recovery circuitry can perform voltage detection and “phase slicing” levels in relation to a center of a pulse or a position between subsequent transitions of a differential signal. A differential data signal has two signals that are typically one hundred eighty degrees out of phase. Each signal can be carried on a separate conductor. These signals are often labeled as a data signal and a complementary data signal and such signals are typically processed by a differential amplifier. Differential amplifiers often have an input offset voltage which adversely affects data transmission. When data is being transmitted, the signal on the data line will have an opposite value of the signal on the complementary data line. Since signals can't transition instantaneously, a picture of a differential signal often looks like two opposing sinusoidal waves that crossover at an average voltage on the graph at various intervals depending on the value of the data being transmitted. Thus, between crossovers of the data waveforms an eye shape is typically formed, often called an eye pattern.

The input offset voltage inherent in differential amplifiers makes it difficult to extract error free data or perform CDR from the communication stream. High performance CDR methods are utilized in many applications such as in routers and switches in telecommunication systems. CDR methods are also utilized by processors within computers that continually exchange data between process cores and memory devices such as random access memory (RAM) or a disk drive. Currently, communication or information systems are transmitting and receiving data in the Gigabit per second range. Increasing the accuracy of CDR amidst noise and distortions often present on a transmission line is a formidable task because the time intervals for signal transitions and steady states can become very small and this requires extreme precision receiving circuits.

As clock and data speeds continue to increase and as voltages levels of the data signal continue to decrease, input offset voltage of the amplifiers in the clock and data recovery circuits has become a very important design challenge. Due to the low signal amplitude and the high input offset in a traditional data reception path, the eye of the incoming data at the sample latch can be “closed” or have a relatively small differential voltage. A sample latch is a portion of the clock and data recovery circuit that acquires the data by sampling the data line at a particular time and latching the value of the incoming data. For a data receiver with multiple data paths and multiple sample latches, it is very challenging to “remove” or compensate for the offset voltage present at nearly every input of every sample latch. Such a compensation for the input offset voltage can preserve the eye shape of the incoming data for each data path or receiving path.

A traditional solution to compensate for input offset voltages is to increase the size of the input devices of the gain stages in the data receiving paths. The proportion of width to length of larger device can is easier to control during manufacturing and such a proportion can dictate a reduced input offset voltage. Accordingly, such large devices can reduce the amount of the input offset voltage, however large devices take up valuable space, are inefficient and consume a relatively large amount of power. Larger devices also cause so many ancillary problems. More specifically, the increased power consumption requires larger supply systems, generates more heat and adversely affects the speed requirements or timing requirements of a design. Accordingly, using such large devices for multiple clock and data recovery circuits is a less than a perfect design solution. In some cases performance cannot be maintained even if power and cooling capacity is increased dramatically.

For example, larger devices typically reduce the allowable clock speeds and/or bandwidth of the data path because of the increased parasitic capacitance caused by the larger devices. This parasitic capacitance slows the rise and fall times of the data waveform thereby limiting the data transfer speeds. Another traditional approach to address input offset issues is to place a calibration stage and a calibration loop on each receiving data path to compensate for the input offset voltage for each data receiving path. This “per path” calibration approach requires a relatively complicated calibration routine and each stage and loop consumes a large amount of the wafer area, power etc. Further Such an approach consumes a relatively large amount of power particularly because of the large number of required calibration loops. Such bulky systems are not optimum in power or area and are generally not competitive.

### SUMMARY

The problems identified above are in large part addressed by the systems, methods and media disclosed herein to provide a low input voltage offset data receiving path. In one embodiment a method is disclosed that includes applying a series of voltages to an input of an offset evaluation latch, detecting an offset voltage from the offset evaluation latch in response to the application of the series of voltages, and applying an offset compensation voltage to the input of a plurality of sampling latch in response to the detected offset voltage. In some embodiments a digital value can be assigned to the applied offset voltage and a programmable voltage, digital to analog converter can accept the digital signal. When the offset voltage is determined, it can be applied to a plurality sampling latches and a data stream can be received and clock and data recovery can be performed. The method can also include buffering the input signal with a buffer and amplifying the input signal. The voltages applied can be positive and negative where each voltage is applied in uniform increments.

In other embodiments a system is disclosed that can include an amplifier to receive differential data where the amplifier can have a first and a second output. The system can also include a plurality of sampling latches, where the latches can have first and second inputs coupled to the first and second output of the amplifier. Further the system can include an offset evaluation latch having a first and second input coupled to the first and second input of the plurality of sampling latches, and a calibration module to apply a series of calibration voltages to the first and second input and to identify an offset voltage of the system.

In other embodiments a computer program product is disclosed that when executed on a computer causes the computer to apply a series of calibration voltages to an output of a gain stage and to an input of an offset evaluation latch, detect an offset voltage from the offset evaluation latch in response to the application of the series of calibration voltages, associate a digital value with the detected offset voltage, and apply an offset compensation voltage to the input of the more than one sampling latch in response to the digital value. In addition when executed the program can cause the computer to latch the digital value if an output of the offset evaluation latch switches states.

In some embodiments when executed the program can cause the computer to apply substantially zero volts on an input of the gain stage as the series of calibration voltages are applied. In yet other embodiments the program when executed can cause the computer to receive a data stream and perform clock and data recovery on the received data stream utilizing the offset voltage.

### BRIEF DESCRIPTION OF THE DRAWINGS

Aspects of the invention will become apparent upon reading the following detailed description and upon reference to the accompanying drawings in which, like references may indicate similar elements:

FIG. 1 illustrates a block diagram of a communication system with a clock and data recovery circuit;

FIG. 2 depicts a calibration table for a input offset calibration system; and

FIG. 3 is a flow diagram for a method of calibrating an input stage for a differential signal;

### DETAILED DESCRIPTION OF EMBODIMENTS

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims.

While specific embodiments will be described below with reference to particular configurations of hardware and/or software, those of skill in the art will realize that embodiments of the present invention may advantageously be implemented with other equivalent hardware and/or software systems. Aspects of the disclosure described herein may be stored or distributed on computer-readable media, including magnetic and optically readable and removable computer disks, as well as distributed electronically over the Internet or over other networks, including wireless networks. Data structures and transmission of data (including wireless transmission) particular to aspects of the disclosure are also encompassed within the scope of the disclosure.

Disclosed herein are arrangements that provide an efficient, compact input voltage offset calibration system that can benefit clock and data recovery (CDR) systems. Generally, the disclosed arrangements can utilize a dedicated calibration sampling latch that has a low input offset voltage where the calibration sampling latch drives a single calibration loop and the single calibration loop can provide offset compensation for multiple sampling latches in a single input multiple output CDR system.

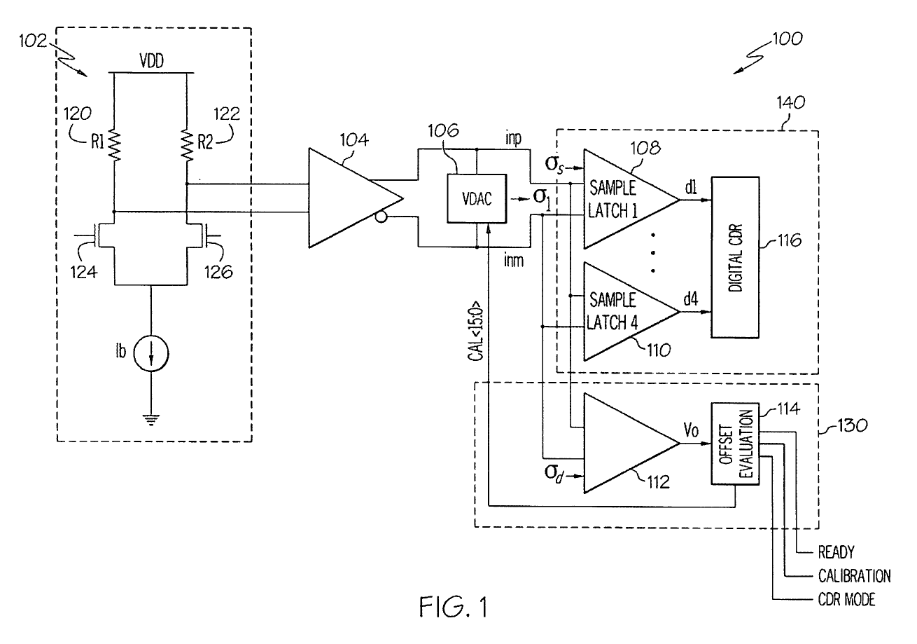

Referring to FIG. 1 a block diagram of a data receiving system 100 is depicted. The system 100 can include a front end differential pair 102, a differential amplifier or gain stage 104, an offset adjustment module 106, a plurality of sampling latches 108 and 110, an offset detection sampler 112, an offset evaluation module 114, and a clock data recovery module 116.

The offset adjustment module 106, the offset detection sampler 112, and the offset evaluation module 114 can form a compensation system 130. The sampling latches 108 and 110 and the CRD 116 can for a core component of a data sampler 140. The system illustrated 100 is a small portion of a clock data recovery system that can accept one bit at a time. In some embodiments, multiple data paths, a plurality of sampling latches, multiple programmable offset adjustment modules in the form of digital to analog converters, and a multiple offset evaluation circuits can form a large CDR system that can accept multiple communication streams in parallel. The system 100 can accept differential data that is received on a data line and a complementary data line by transistors 124 and 126 such that when one line provides a logic high value the other line provides a logic low value and vice-versa.

The sampling latches 108 and 110 can perform clock and data recovery with the assistance of CDR module 116, and a clock signal and can adjust an inherent input offset voltage of the gain stage 104. In one embodiment, the sampling latches 108 and 110 can receive data at rates in excess of three Gigabits per seconds. At such high data rates, and low voltages accurate reading of the data can require the input offset voltage be of the system be improved. Reducing the input offset can increase the accuracy of the received data and reduce the error rate of the communication.

The asymmetrical mismatch between the resistance value provided by resistor 120 and 122 and by transistors 124 and 126 of the differential pair 102 can cause an input offset voltage at the input of the system 100 and at the output of the gain stage 104. The input offset voltage can be understood as a voltage which when applied between the input terminals on transistor 124 and 126 can create a zero output voltage at the output of gain stage 104. Thus, applying an offset calibration voltage can “trim” the system or calibrate the system. The input offset voltage can also be defined as a voltage differential that when applied at the input of the system 100 will provide improved clock and data recovery performance because the system and/or the latches are “balanced” around zero volts. In addition, the data received at the input of transistors 124 and 126 may have a direct Current (DC) offset. In high speed, low voltage communication systems such offsets can cause significant data errors and balancing the system around zero volts can provide a significant improvement in performance.

Any offset voltage can be amplified when successive gain stages are utilized. Accordingly, when each gain stage has an input offset voltage, the input offset voltage of each stage can add up (two stages are illustrated) and thus, an undesirably large input offset voltage can often occur at the inputs to the sample latches 108 and 110. Such an input offset voltage can greatly reduce the shape of the eye of incoming data and such a shape is important for successfully achieving clock and data recovery from a differential signal at high clock speeds and low voltages. Accordingly, the compensation portion of the system 100 can compensate for the offset of the gain stage 104 and a portion of the offset voltage of the sampling latches 108 and 110. In addition, different sample latches (108 and 110) can have different offsets and not all of such offsets can be calibrated out.

Thus, it is desirable to adjust the voltage offset of the system 100 at the output of gain stage 104 such that an acceptable eye shaped signal (data waveform) is provided to the sampling latches 108 and 110. To reduce and possibly eliminate the offset voltage or effects of the offset voltage due to device mismatches in the data path, a compensation voltage call be determined by the offset detection latch 112 which drives the offset evaluation module 114. Thus once calibrated, the offset evaluation module 114 can provide or control the offset adjustment module 106 and the offset adjustment module 106 can provide a compensation voltage to the inputs of the plurality of sample latches 108 and 110. The offset adjustment module 106 can be a programmable voltage, digital to analog converter (VDAC) that accepts a digital value and converts the digital value or signal into an analog voltage at its output.

The system can have two modes, a calibration mode, and an operational or data receiving mode. During calibration a controller (not shown) can control the offset evaluation module 114 to step through the calibration voltages provided to the offset adjustment module 106 and to monitor the output of the offset evaluation latch 112. The differential pair 102 can be turned off such that zero volts are applied across the input of the gain stage. The calibration voltages as provided by the offset adjustment module 106 and controlled by the offset evaluation module 114 can start at the most negative or the most positive value and increment in equal steps and when the offset voltage of the amplifier/gain stage 104 is reached, the voltage at the output of the offset evaluation latch 112 can toggle. The offset evaluation latch 112 can be a precision device that toggles when its input voltage crosses through zero volts.

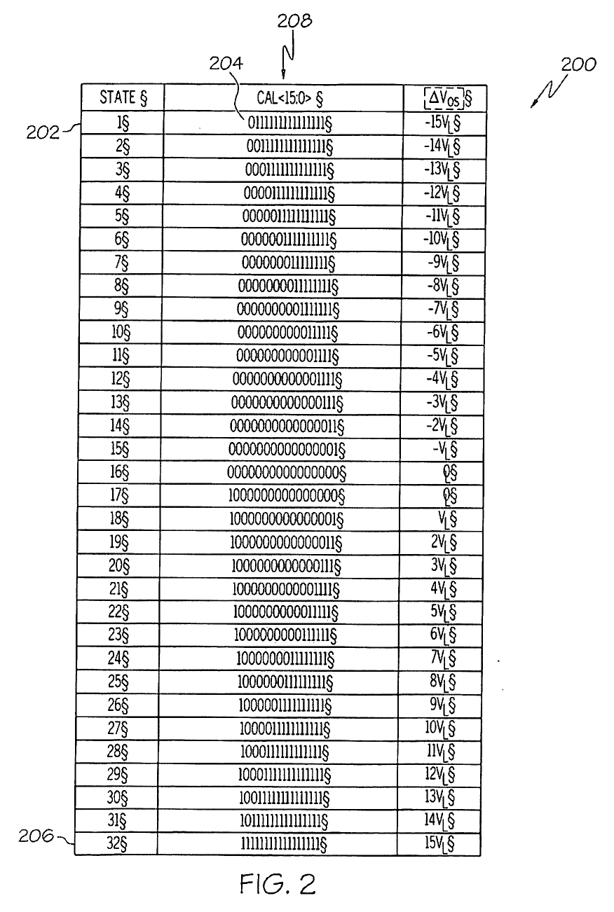

In some embodiments, thirty two different voltages can be applied as calibration voltages to create a span of 30 micro volts, (15 micro volts positive and 15 micro volts negative). The calibration voltages can have thirty two identical increments and the increments can be controlled by changing the sixteen bit control signal supplied to the offset adjustment module 106 as illustrated by the table of FIG. 2. After a calibration process where an appropriate compensation voltage and corresponding digital control value is determined, the system can change to an operational mode, where the offset adjustment module 106 can trim the output Of the gain stage 104 in response the proper sixteen bit control signal provided by the offset evaluation module 114.

In some embodiments, to provide improved sensitivity and resolution the offset voltage at the output of the gain stage can be amplified by the dedicated “high gain” low offset, offset detection buffer 112. Stepping through different voltage during the calibration stage can allow the offset evaluation module 114 to determine the polarity and magnitude of the offset voltage of the gain stage 104 and when configured appropriately the system can determine the offset voltage of the differential amplifier 102 and can compensate for this offset.

When the calibration voltages are stepped through and the output of the offset evaluation buffer 112 reaches zero volts, then the offset evaluation module 114 can stop the calibration process at such a voltage and can store the digital control value associated with the analog voltage that makes the output of the offset evaluation buffer 112 zero or near zero volts. In some embodiments, in the automated calibration mode, data can be received by the latches and the offset voltage can be varied until the data error rate in minimized. In addition to the offset voltage being stepped through a variety of voltages, the voltage differential of the incoming data can be minimized such that the offset can be fine tuned.

In some embodiments, with a minimal voltage differential on the incoming differential data signal, the offset evaluation module 114 can step through thirty two different compensation voltages (sixteen positive voltages and sixteen negative voltages) sequentially to determine which offset provides the lowest data error rate. For each step (or for every magnitude and every polarity) the output voltage of the offset detection buffer 112 can be monitored to determine what offset voltage provides an acceptable performance.

The control signal from the offset evaluation module 114 can be set, and based on the control signal from the offset evaluation module 114, the offset adjustment module 106 can provide the desired offset to the input of the sample latches 108 and 110. Thus, the offset voltage that is “seen” by the sampling latches can be “canceled” or compensated by the offset compensation system such that the receiver/system 100 can have a reduced error rate. Only two sampling latches are explicitly illustrated (i.e. 1-4 really four are technically illustrated) however, many or “n” sampling latches could be controlled by the offset compensation system 130. The upper limit on the number of latches is somewhat arbitrary, however limited by the performance and allowable capacitive load created by each latch.

It can be appreciated that the offset detection buffer 112 can be a precision device, possibly a larger device that has with an input offset that is significantly smaller that the offset of the latches 108 and 110. The input offset of the offset detection buffer 112 can also be significantly smaller than the detected offset voltage. The offset precision of the offset detection buffer 112 can assist in reducing the portion of the offset of the system which is due to random effects related to the smaller size of the transistors in the sampling latches and such an offset can be reduced by cancelling out at least a portion of the offset voltage.

In some embodiments to make the system 100 more efficient, the offset detection buffer 112 can be turned off after the calibration is completed. Generally, the more accurate the offset detection buffer, the better the accuracy of the steady state offset voltage, and the better the performance of the system 100 of course within certain boundaries.

The disclosed calibration arrangements can improve the performance of clock and data recovery systems that have multiple data paths with tight power and area constraints. The offset compensation arrangements provided utilize a dedicated (and accurate) sampling latch or offset detection buffer 112 that is dedicated to the offset compensation feedback loop and thus can be idle during operation or during clock and data recovery. Thus, the disclosed offset calibration scheme can remove the offset for multiple data paths and multiple sample latch systems by sourcing or sinking current at the output of the gain stage 106.

It can be appreciated that an offset correction, single feedback loop can be utilized to reduce the input offset voltage for multiple sampling latches 108 and 110. Such a single feedback loop requires substantially less power than required by traditional solutions with multiple loops per data path to address input offset problems. The disclosed system 100 can be effectively utilized in high-speed digital data transmissions from chip-to-chip over short electrical links. One such configuration would be in a router or a switch in a telecommunications system that supports the Internet where the highest possible data rate with the lowest possible error rate is desired.

The receiver system can be implemented by a set of electrical components that are integrated on an integrated circuit or chip with many other devices or components that provide many other functions. Likewise, the receiver system 100 can be integrated with other devices on the same chip and can be part of a “system-on-a-chip.” The system 100 can move data in the multiple Gigabits per second range from chip-to-chip over wired media, such as a backplane of a state-of-the-art router.

Offset in CDR systems can generally be defined as the true versus the complement inputs For example, the inputs to the gain stage 104 can be held at a quiescent level at the same voltage (both common mode and differential). The output of the gain stage at this zero input voltage with a zero offset voltage would be zero as well. When such a phenomena does not occur the disclosed system 100 can negate at least a portion of this offset. During the calibration mode the input data line can be set to zero volts as part of a start up function, however this is not necessary with appropriate controls. It can be appreciated that the devices illustrated can be manufactured in close proximity on the die such that they have similar offsets.

Referring to FIG. 2, a table 200 of digital values and analog voltages that can be utilized during a calibration process. Thirty two different calibration voltages are illustrated, however any number of calibration voltages could be utilized to calibrate a system without parting from the scope of this disclosure. In FIG. 2 different calibration voltages depicted by states one (202) to thirty two 32 (206) are illustrated. State one has a calibration voltage of minus fifteen micro volts, where state sixteen has a calibration voltage of zero volts and state thirty two has a calibration voltage of positive fifteen micro volts. The calibration voltages shown step down, or up in equal increments of one micro volt however non uniform steps or increments would not part from the scope of the disclosure.

The digital value that can be sent to a programmable voltage, digital to analog converter can control the magnitude of the voltage applied to the output of the gain stage or the input of the sampling latches is illustrated in column 208. As illustrated by line one, or state one, 202 a digital value of “0111111111111111” can be generated by the calibration system and the digital to analog converter or offset adjustment module 106 can convert this digital value to an analog signal/voltage of negative 15 micro-volts. Such a voltage can be applied to the inputs of an offset calibration latch as well as other sampling latches to bias the inputs of the calibration latches around zero volts.

The most significant bit 204 of the digital value can dictate the polarity of the calibration voltage. For example, a logical one or a logic high in the most significant bit or the left most position can dictate a positive calibration voltage and a logical zero in the most significant bit can dictate a negative calibration voltage. When power is applied to the system the calibration portion of the system can start with values provided at the top or bottom of the table, which represents a minimum or a maximum, and can progress through the table providing each value in the table, monitoring the output of an offset detection latch. In some embodiments when the output of the gain stage “crosses” zero volts the calibration process can stop such that it does not progress through each value. When the value crosses zero, then the offset evaluation module can store the digital value that makes the gain stage output zero volts for use during operation/data reception.

In some embodiments, once the state (i.e. 1-32) that causes a zero volt output of the gain stage is determined, the offset evaluation logic can latch its output (or output value) such that it provides the appropriate voltage compensation, and then the offset evaluation logic can send a ready signal to a controller and data can be received or clock and data recovery can be performed. It can be appreciated that a single offset evaluation circuit can adjust the offset voltage for many sampling latches possibly seven or eight sampling latches as a single received data stream can be provided to a plurality of sampling latches.

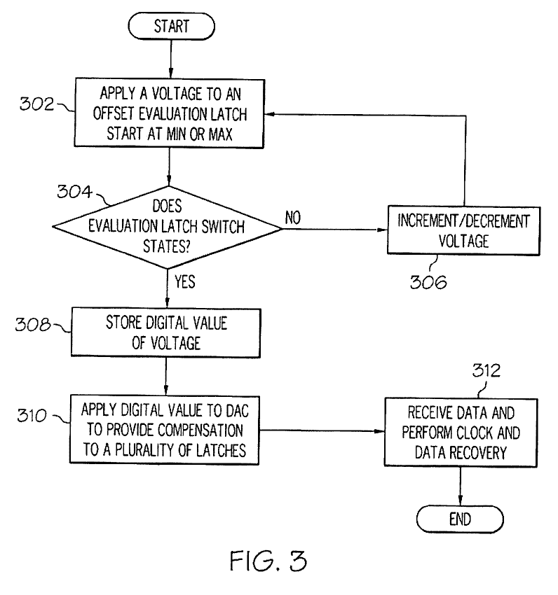

Referring to FIG. 3, flow diagram depicting a method 300 for calibrating input offset voltage for a clock and data recovery (CDR) system is depicted. As illustrated by block 302, an input of a gain stage can be set at zero volts and a calibration voltage can be applied to the output of the gain stage and correspondingly to an input of an offset evaluation latch. The calibration voltage input can also be applied to a plurality of sampling latches connected in parallel with the offset evaluation latch. As illustrated by decision block 304, the output of the latch can be monitored to see if the output offset evaluation latch toggles to a different state as the input of the offset evaluation latch crosses through zero volts. If the evaluation latch does not switch states, then the offset calibration voltage can be incremented or decremented as illustrated by block 306 and the “new” incremented/decremented voltage can be applied to the offset evaluation latch as illustrated by block 302.

If, at decision block 304 the offset calibration voltage switches the output state of the offset evaluation latch, then the digital value that switches the evaluation latch can be stored by the system as illustrated by block 308. As illustrated by block 310, the stored digital value can be applied to a digital to analog converter to provide an offset compensation voltage or a bias voltage to a plurality of sampling latches as illustrated by block 310. Data can be received and the biased sampling latches can perform clock and data recovery on the incoming data as illustrated by block 312.

As stated above, the output voltage of the latch can be monitored in response to the application of each voltage of the series of calibration voltages and when the output of the offset evaluation latch switches states, an offset voltage can be determined. In some embodiments sixteen positive voltages and sixteen negative voltages having equal increments can be applied to the input of sampling latches by the digital to analog converter.

Each process disclosed herein could be implemented with a software program. The embodiment depicted uses a finite state machine to control the calibration algorithm. The software programs described herein may be operated on any type of computer, such as personal computer, server, etc. Any programs may be contained on a variety of signal-bearing media. Illustrative signal-bearing media include, but are not limited to: (i) information permanently stored on non-writable storage media (e.g., read-only memory devices within a computer such as CD-ROM disks readable by a CD-ROM drive); (ii) alterable information stored on writable storage media (e.g., floppy disks within a diskette drive or hard-disk drive); and (iii) information conveyed to a computer by a communications medium, such as through a computer or telephone network, including wireless communications. The latter embodiment specifically includes information downloaded from the Internet, intranet or other networks. Such signal-bearing media, when carrying computer-readable instructions that direct the functions of the present invention, represent embodiments of the present disclosure.

The disclosed embodiments can take the form of an entirely hardware embodiment, an entirely software embodiment or an embodiment containing both hardware and software elements. in a preferred embodiment, the invention is implemented in software, which includes but is not limited to firmware, resident software, microcode, etc. Furthermore, the invention can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk—read only memory (CD-ROM), compact disk—read/write (CD-R/W) and DVD. A data processing system suitable for storing and/or executing program code can include at least one processor, logic, or a state machine coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

It will be apparent to those skilled in the art having the benefit of this disclosure that the present invention contemplates methods, systems, and media that provide an improved data recovery system. It is understood that the form of the invention shown and described in the detailed description and the drawings are to be taken merely as examples. It is intended that the following claims be interpreted broadly to embrace all the variations of the example embodiments disclosed.

What is claimed is:

1. A method comprising:
applying a series of calibration voltages to an output of a gain stage and to an input of an offset evaluation latch;
detecting an offset voltage from the offset evaluation latch in response to the application of the series of calibration voltages;
associating a digital value with the detected offset voltage; and
applying an offset compensation voltage to the input of the more than one sampling latch in response to the digital value.

2. The method of claim 1, further comprising latching the digital value if an output of the offset evaluation latch switches states.

3. The method of claim 1, further comprising applying substantially zero volts on an input of the gain stage as the series of calibration voltages are applied.

4. The method of claim 1, further comprising converting the digital value to an analog voltage.

5. The method of claim 1, further comprising receiving a data stream and performing clock and data recovery on the received data stream utilizing the offset voltage.

6. The method of claim 1, further comprising receiving an input signal.

7. The method of claim 6, further comprising buffering and amplifying the input signal.

8. The method of claim 1, wherein the series of calibration voltages comprise positive voltages and negative voltages.

9. The method of claim 1 further comprising detecting an error rate and adjusting the offset voltage in response to the error rate.

10. A system comprising:
an amplifier to receive differential data, the amplifier having a first and a second output;
a plurality of sampling latches having a first and second input coupled to the first and second output of the amplifier;
an offset evaluation latch having a first and second input coupled to the first and second input of the plurality of sampling latches; and
a calibration module coupled to the plurality of sampling latches to apply a series of calibration voltages to the first and second input of the first and second inputs of the sampling latches and the offset evaluation latch, to determine an offset voltage of the system and to apply the determined offset voltage to the first and second inputs of the plurality of sampling latches compensation during operation.

11. The system of claim 10, further comprising a clock and data recovery module coupled to an output of at least one of the plurality of sampling latches.

12. The system of claim 10, wherein the calibration module comprises a digital to analog converter.

13. The system of claim 12 wherein the calibration module comprises a programmable voltage digital to analog converter.

14. The system of claim 10, wherein the offset evaluation latch has an offset voltage of less than 10 milli-volts.

15. A computer program product comprising a computer useable medium having a computer readable program, wherein the computer readable program when executed on a computer causes the computer to:
apply a series of calibration voltages to an output of a gain stage and to an input of an offset evaluation latch;
detect an offset voltage from the offset evaluation latch in response to the application of the series of calibration voltages;
associate a digital value with the detected offset voltage; and
apply an offset compensation voltage to the input of the more than one sampling latch in response to the digital value.

16. The computer program product of claim 15, further comprising a computer readable program when executed on a computer causes the computer to latch the digital value if an output of the offset evaluation latch switches states.

17. The computer program product of claim 15, further comprising a computer readable program when executed on a computer causes the computer to apply substantially zero volts on an input of the gain stage as the series of calibration voltages are applied.

18. The computer program product of claim 15, further comprising a computer readable program when executed on a computer causes the computer to convert the digital value to an analog voltage.

19. The computer program product of claim 15, further comprising a computer readable program when executed on a computer causes the computer to receive a data stream and performing clock and data recovery on the received data stream utilizing the offset voltage.

20. The computer program product of claim 15, further comprising a computer readable program when executed on a computer causes the computer to receive an input signal.
